(19) United States
(12) Patent Application Publication
(10) Pub. No.: US 2026/0324233 A1
(43) Pub. Date: Oct. 15, 2026

(54) DISPLAY SUBSTRATE AND DISPLAY DEVICE

(71) Applicant: BOE TECHNOLOGY GROUP CO., LTD., Beijing (CN)

(72) Inventors: Jianchao ZHU, Beijing (CN); Shiming SHI, Beijing (CN); Yu FENG, Beijing (CN); Libin LIU, Beijing (CN)

(73) Assignee: BOE TECHNOLOGY GROUP CO., LTD., Beijing (CN)

(21) Appl. No.: 18/866,803

(22) PCT Filed: Dec. 1, 2023
(86) PCT No.: PCT/CN2023/135917

§ 371 Date: Nov. 18, 2024

(51) Int. Cl. H10K 59/131; H10K 59/122; H10K 59/80

(52) U.S. Cl. CPC H10K 59/1315; H10K 59/122; H10K 59/80521; H10K 59/8723; H10K 59/873

(57) ABSTRACT

A display substrate and a display device. The display substrate includes a base substrate, a plurality of cathode lines, a planarization layer, a pixel definition layer, and a plurality of light emitting elements; the plurality of cathode lines are located on the base substrate; the planarization layer is located at a side of the cathode lines away from the base substrate; the pixel definition layer is located at a side of the planarization layer away from the cathode lines; the display substrate further includes a plurality of conductive isolation columns, the conductive isolation columns are arranged in one-to-one correspondence with the light emitting elements, each conductive isolation column is electrically connected with one cathode line, and each light emitting element includes an anode, a light emitting layer and a cathode, and the cathode of each light emitting element is electrically connected with a corresponding conductive isolation column.

### TECHNICAL FIELD

Embodiments of the present disclosure relate to a display substrate and a display device.

### BACKGROUND

With the continuous development of display technology, organic light emitting diode display devices (OLED) have been widely used in various electronic products due to their advantages such as wide color gamut, high contrast, thin and light design, self-luminescence, and wide viewing angle, ranging from small electronic products such as smart bracelets, smart watches, smart phones, tablet computers, to large electronic products such as laptop computers, desktop computers and televisions. Therefore, the market demand for organic light emitting diode display devices is further growing.

### SUMMARY

Embodiments of the present disclosure provide a display substrate and a display device. A cathode of each of light emitting elements in the display substrate can be connected with a cathode line below a planarization layer through a conductive isolation column, thus a cathode voltage can be applied to the cathode of each of the light emitting elements through the cathode line under the planarization layer. With such arrangement, the display substrate can realize that different light emitting elements use independent cathodes, apply different cathode voltages, to realize that each of the light emitting elements uses a suitable cathode voltage, and avoids redundant voltage and redundant power consumption, thus an overall power consumption of the display substrate is reduced. On the other hand, the conductive isolation column itself can also play a certain isolation role to prevent cathodes of adjacent light emitting elements from overlapping.

At least one embodiment of the present disclosure provides a display substrate, which includes: a base substrate; a plurality of cathode lines, located on the base substrate; a planarization layer, located at a side of the plurality of cathode lines away from the base substrate; a pixel definition layer, located at a side of the planarization layer away from the plurality of cathode lines; and a plurality of light emitting elements, the display substrate further includes a plurality of conductive isolation columns, the plurality of conductive isolation columns are arranged in one-to-one correspondence with the plurality of light emitting elements, each of the plurality of conductive isolation columns is electrically connected with one of the plurality of cathode lines, and each of the light emitting elements includes an anode, a light emitting layer and a cathode, and the cathode of each of the light emitting elements is electrically connected with a corresponding conductive isolation column of the plurality of conductive isolation columns.

For example, in the display substrate provided by an embodiment of the present disclosure, the display substrate further includes: a plurality of pixel driving circuits, located at a side of the planarization layer close to the base substrate, the plurality of pixel driving circuits are arranged in one-to-one correspondence with the plurality of light emitting elements, and the anode of each of the light emitting elements is electrically connected with an output end of a corresponding pixel driving circuit of the plurality of pixel driving circuits.

For example, in the display substrate provided by an embodiment of the present disclosure, each of the plurality of conductive isolation columns is at least partially located at a side of the pixel definition layer away from the base substrate, and each of the plurality of conductive isolation columns is electrically connected with one of the cathode lines through a via hole passing through both the pixel definition layer and the planarization layer.

For example, in the display substrate provided by an embodiment of the present disclosure, each of the plurality of conductive isolation columns is partially located in the via hole passing through both the pixel definition layer and the planarization layer.

For example, in the display substrate provided by an embodiment of the present disclosure, the cathode of each of the light emitting elements is overlapped with a lateral surface of a corresponding conductive isolation column of the plurality of conductive isolation columns.

For example, in the display substrate provided by an embodiment of the present disclosure, the cathode of each of the light emitting elements is arranged in contact with the lateral surface of the corresponding conductive isolation column.

For example, in the display substrate provided by an embodiment of the present disclosure, the cathode of each of the light emitting elements is connected with the lateral surface of the conductive isolation column through a conductive structure.

For example, in the display substrate provided by an embodiment of the present disclosure, the plurality of light emitting elements include a first light emitting element, a second light emitting element and a third light emitting element, the first light emitting element includes a first anode, a first light emitting layer and a first cathode, the second light emitting element includes a second anode, a second light emitting layer, and a second cathode, the third light emitting element includes a third anode, a third light emitting layer and a third cathode, the first anode and the first cathode are configured to drive the first light emitting layer to emit light of a first color, the second anode and the second cathode are configured to drive the second light emitting layer to emit light of a second color, and the third anode and the third cathode are configured to drive the third light emitting layer to emit light of a third color.

For example, in the display substrate provided by an embodiment of the present disclosure, the plurality of cathode lines include a first cathode line, a second cathode line and a third cathode line, the plurality of conductive isolation columns include a first conductive isolation column, a second conductive isolation column and a third conductive isolation column, the first conductive isolation column is electrically connected with the first cathode line and the first cathode of the first light emitting element respectively, the second conductive isolation column is electrically connected with the second cathode line and the second cathode of the second light emitting element respectively, and the third conductive isolation column is electrically connected with the third cathode line and the third cathode of the third light emitting element respectively.

For example, in the display substrate provided by an embodiment of the present disclosure, the first cathode line, the second cathode line, and the third cathode line are configured to be loaded with different cathode voltages.

For example, in the display substrate provided by an embodiment of the present disclosure, an orthographic projection of the first conductive isolation column on the base substrate is located at periphery of an orthographic projection of the first light emitting element on the base substrate, an orthographic projection of the second conductive isolation column on the base substrate is located at periphery of an orthographic projection of the second light emitting element on the base substrate, and an orthographic projection of the third conductive isolation column on the base substrate is located at periphery of an orthographic projection of the third light emitting element on the base substrate.

For example, in the display substrate provided by an embodiment of the present disclosure, the first color is red, the second color is green, and the third color is blue.

For example, in the display substrate provided by an embodiment of the present disclosure, the first light emitting element further includes a first opening, located in the pixel definition layer, the first anode is located at a side of the pixel definition layer close to the base substrate, and is exposed by the first opening, and the first light emitting layer is at least partially located in the first opening, to contact with the first anode; the second light emitting element further includes a second opening, located in the pixel definition layer, the second anode is located at a side of the pixel definition layer close to the base substrate, and is exposed by the second opening, and the second light emitting layer is at least partially located in the second opening, to contact with the second anode; and the third light emitting element further includes a third opening located in the pixel definition layer, the third anode is located at a side of the pixel definition layer close to the base substrate, and is exposed by the third opening, and the third light emitting layer is at least partially located in the third opening, to contact with the third anode.

For example, in the display substrate provided by an embodiment of the present disclosure, an orthographic projection of the first conductive isolation column on the base substrate surrounds an orthographic projection of the first opening of the first light emitting element on the base substrate, an orthographic projection of the second conductive isolation column on the base substrate surrounds an orthographic projection of the second opening of the second light emitting element on the base substrate, and an orthographic projection of the third conductive isolation column on the base substrate surrounds an orthographic projection of the third opening of the third light emitting element on the base substrate.

For example, in the display substrate provided by an embodiment of the present disclosure, an orthographic projection of the first conductive isolation column on the base substrate half surrounds an orthographic projection of the first opening of the first light emitting element on the base substrate, an orthographic projection of the second conductive isolation column on the base substrate half surrounds an orthographic projection of the second opening of the second light emitting element on the base substrate, and an orthographic projection of the third conductive isolation column on the base substrate half surrounds an orthographic projection of the third opening of the third light emitting element on the base substrate, only one conductive isolation column is arranged between the first light emitting element and the second light emitting element that are adjacent to each other, between the second light emitting element and the third light emitting element that are adjacent to each other, and between the first light emitting element and the third light emitting element that are adjacent to each other, respectively.

For example, in the display substrate provided by an embodiment of the present disclosure, an orthographic projection of the first conductive isolation column on the base substrate is located at a side of an orthographic projection of an edge of the first opening of the first light emitting element on the base substrate, an orthographic projection of the second conductive isolation column on the base substrate is located at a side of an orthographic projection of an edge of the second opening of the second light emitting element on the base substrate, and an orthographic projection of the third conductive isolation column on the base substrate is located at a side of an orthographic projection of an edge of the third opening of the third light emitting element on the base substrate.

For example, in the display substrate provided by an embodiment of the present disclosure, the display substrate further includes: a first temporary encapsulation layer, located at a side of the first light emitting element away from the base substrate; a second temporary encapsulation layer, located at a side of the second light emitting element away from the base substrate; and a third temporary encapsulation layer, located at a side of the third light emitting element away from the base substrate; the first temporary encapsulation layer, the second temporary encapsulation layer and the third temporary encapsulation layer are independent with each other, and are spaced apart from each other.

For example, in the display substrate provided by an embodiment of the present disclosure, the display substrate further includes: an encapsulation layer, located at a side of the first temporary encapsulation layer, the second temporary encapsulation layer and the third temporary encapsulation layer away from the base substrate.

For example, in the display substrate provided by an embodiment of the present disclosure, an orthographic projection of each of the plurality of conductive isolation columns on the base substrate surrounds an orthographic projection of a corresponding light emitting element on the base substrate respectively.

For example, in the display substrate provided by an embodiment of the present disclosure, an orthographic projection of each of the plurality of conductive isolation columns on the base substrate half surrounds an orthographic projection of a corresponding light emitting element on the base substrate.

For example, in the display substrate provided by an embodiment of the present disclosure, an orthographic projection of each of the plurality of conductive isolation columns on the base substrate is located at a side of an orthographic projection of an edge of a corresponding light emitting element on the base substrate.

For example, in the display substrate provided by an embodiment of the present disclosure, only one of the conductive isolation columns is arranged between two adjacent light emitting elements.

For example, in the display substrate provided by an embodiment of the present disclosure, the display substrate further includes: a plurality of cathode connection lines, each of the cathode connection lines is electrically connected with at least two cathode lines of the plurality of cathode lines, each of the cathode connection lines is located in a first conductive layer and extends along a first direction, each of the cathode lines is located in a second conductive layer and extends along a second direction, and the first direction is intersected with the second direction.

For example, in the display substrate provided by an embodiment of the present disclosure, the plurality of cathode lines include a plurality of first cathode lines, a plurality of second cathode lines and a plurality of third cathode lines, the plurality of cathode connection lines include a first cathode connection line, a second cathode connection line and a third cathode connection line, two of the first cathode lines adjacent to each other in the first direction are electrically connected with a same first cathode connection line, two of the second cathode lines adjacent to each other in the first direction are electrically connected with a same second cathode connection line, and two of the third cathode lines adjacent to each other in the first direction are electrically connected with a same third cathode connection line.

For example, in the display substrate provided by an embodiment of the present disclosure, the first cathode connection line, the second cathode connection line and the third cathode connection line are arranged along the second direction.

At least one embodiment of the present disclosure further provides a display device, including any one of the abovementioned display substrate.

### BRIEF DESCRIPTION OF DRAWINGS

In order to more clearly explain the technical solution of the embodiments of the present disclosure, the accompanying drawings of the embodiments will be briefly introduced below. Obviously, the accompanying drawings in the following description only relate to some embodiments of the present disclosure, and are not limited to the present disclosure.

FIG. 1A is a structural schematic diagram of a display substrate provided by an embodiment of the present disclosure;

FIG. 1B is a schematic diagram of an overlapping between a cathode of another light emitting element and the corresponding conductive isolation column provided by an embodiment of the present disclosure;

FIG. 2 is a planar schematic diagram of a display substrate provided by an embodiment of the present disclosure;

FIG. 3 is a schematic diagram of stacking of light emitting elements and conductive isolation columns in a display substrate provided by an embodiment of the present disclosure;

FIG. 4 is a schematic diagram of a plurality of cathode lines in a display substrate provided by an embodiment of the present disclosure;

FIG. 5 is a s planar schematic diagram of another display substrate provided by an embodiment of the present disclosure;

FIG. 6 is a schematic diagram of stacking of light emitting elements and conductive isolation columns in another display substrate provided by an embodiment of the present disclosure;

FIG. 7 is a schematic diagram of cathode lines in another display substrate provided by an embodiment of the present disclosure;

FIG. 8 is a structural schematic diagram of a display substrate provided by an embodiment of the present disclosure;

FIG. 9 is a schematic diagram of stacking of light emitting elements and conductive isolation columns in another display substrate provided by an embodiment of the present disclosure;

FIG. 10 is a schematic diagram of cathode lines of another display substrate provided by an embodiment of the present disclosure;

FIG. 11 is a schematic diagram of stacking of light emitting elements and conductive isolation columns in another display substrate provided by an embodiment of the present disclosure;

FIG. 12 is a schematic diagram of cathode lines of another display substrate provided by an embodiment of the present disclosure;

FIG. 13 is a schematic diagram of stacking light emitting elements and conductive isolation columns in another display substrate provided by an embodiment of the present disclosure;

FIG. 14 is a schematic diagram of cathode lines of another display substrate provided by an embodiment of the present disclosure;

FIG. 15 is a schematic diagram of stacking of light emitting elements and conductive isolation columns in another display substrate provided by an embodiment of the present disclosure;

FIG. 16 is a schematic diagram of cathode lines of another display substrate provided by an embodiment of the present disclosure; and

FIG. 17 is a schematic diagram of a display device provided by an embodiment of the present disclosure.

### DETAILED DESCRIPTION

In order to make objects, technical details and advantages of the embodiments of the present disclosure apparent, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects.

Unless otherwise defined, the features such as “parallel”, “vertical” and “identical” used in the embodiments of the present disclosure all comprise situations such as “parallel”, “vertical” and “identical” in a strict sense, and situations such as “substantially parallel”, “substantially vertical” and “substantially identical” that contain the cases of certain errors. For example, the above-mentioned term “substantially” means that the difference of the compared objects is within 10% or 5% of the average value of the compared objects. When the number of one component or element is not specified in the following of the embodiments of the present disclosure, it means that the component or element may be one or more, or may be understood as at least one. “At least one” means one or more, and “multiple/a plurality of” means at least two. The term “in a same layer” in the embodiments of the present disclosure refers to the relationship between multiple layers formed by the same material after the same one step (for example, one-step patterning process). The term “same layer” here does not always mean that the thickness of multiple layers is the same or the height of multiple layers in cross-sectional view is the same.

With the pursuit of high display quality and the advancement of technology, the resolution of the organic light emitting diode display devices is continuously improved. Under certain process capability limitations, since the mainstream technology for patterning a sub-pixel light emitting region of an organic light emitting diode display device is a fine metal mask (FMM), which is unable to form patterns of smaller sizes, so that the manufacture of an organic light emitting diode display device with a high resolution is greatly restricted.

On the other hand, due to differences in structure and efficiency of the organic light emitting elements of different colors, in actual applications, there are differences in the operating currents of the organic light emitting elements of different colors (for example, red organic light emitting elements, green organic light emitting elements, and blue organic light emitting elements). In a conventional organic light emitting diode display device, organic light emitting elements of different colors share a common cathode, therefore, in a case where the cathode voltage is set, it is necessary to meet a voltage required by the organic light emitting element with a maximum operating current, that is, the cathode voltage is set to a voltage required by the organic light emitting element with the maximum operating current. At this time, other organic light emitting elements with smaller working currents have problems of redundant voltage and redundant power consumption.

In this regard, an embodiment of the present disclosure provides a display substrate, which includes a base substrate, a plurality of cathode lines, a planarization layer, a pixel definition layer, and a plurality of light emitting elements; the plurality of cathode lines are located on the base substrate; and the planarization layer is located at a side of the plurality of cathode lines away from the base substrate; the pixel definition layer is located at a side of the planarization layer away from the plurality of cathode lines; the display substrate further includes a plurality of conductive isolation columns arranged one-to-one corresponding to the plurality of light emitting elements, each of the plurality of conductive isolation columns is electrically connected with one of the plurality of cathode lines, and each of the plurality of light emitting elements includes an anode, a light emitting layer and a cathode, the cathode of each of the plurality of light emitting elements is electrically connected with a corresponding conductive isolation column of the plurality of conductive isolation columns. In this way, the cathode of each of the plurality of light emitting elements in the display substrate can be connected with a cathode line below the planarization layer through a conductive isolation column, thus a cathode voltage can be applied to the cathode of each of the plurality of light emitting elements through the cathode line under the planarization layer. With such arrangement, the display substrate can realize that different light emitting elements use independent cathodes and apply different cathode voltages, which enables that each of the plurality of light emitting elements use a suitable cathode voltage, avoids redundant voltage and redundant power consumption, and thus reduces an overall power consumption of the display substrate.

The embodiment of the present disclosure further provides a display device, which includes the above-mentioned display substrate. In this way, the display device also has the advantages of low power consumption.

Hereinafter, the display substrate and the display device provided by the embodiments of the present disclosure are described in detail below with reference to the accompanying drawings.

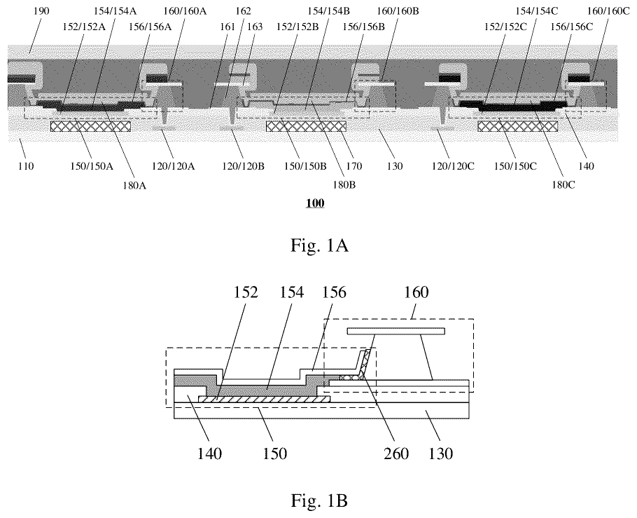

FIG. 1A is a structural schematic diagram of a display substrate provided by an embodiment of the present disclosure. As illustrated by FIG. 1A, the display substrate 100 includes a base substrate 110, a plurality of cathode lines 120, a planarization layer 130, a pixel definition layer 140, and a plurality of light emitting elements 150; the plurality of cathode lines 120 are located on the base substrate 110; the planarization layer 130 is located at a side of the plurality of cathode lines 120 away from the base substrate 110; and the pixel definition layer 140 is located at a side of the planarization layer 130 away from the plurality of cathode lines 120.

For example, as illustrated by FIG. 1A, each of the plurality of the cathode lines 120 is configured to provide a cathode voltage to a cathode of a light emitting element, to drive the light emitting element to emit light; the plurality of cathode lines may provide different cathode voltages, that is, the cathode voltages on the plurality of cathode lines may include a plurality of different cathode voltages.

As illustrated by FIG. 1A, the display substrate 100 further includes a plurality of conductive isolation columns 160 arranged in one-to-one correspondence with the plurality of light emitting elements 150, each of the plurality of conductive isolation columns 160 is electrically connected with a cathode line 120, each of the plurality of light emitting elements 150 includes an anode 152, a light emitting layer 154, and a cathode 156, and a cathode 156 of each of the plurality of light emitting elements 150 is electrically connected with a corresponding conductive isolation column 160 of the plurality of conductive isolation columns 160.

In the display substrate provided by the embodiment of the present disclosure, the cathode of each of the plurality of light emitting elements in the display substrate can be connected with the cathode line under the planarization layer through a conductive isolation column. Therefore, a cathode voltage can be applied to the cathode of each of the plurality of light emitting elements through the cathode line under the planarization layer. With such arrangement, the display substrate can realize that different light emitting elements use independent cathodes, apply different cathode voltages, enables each of the plurality of light emitting elements to use a suitable cathode voltage, avoids redundant voltage and redundant power consumption, and thus reduces the overall power consumption of the display substrate. On the other hand, the conductive isolation column itself can also play a certain isolation role to prevent cathodes of adjacent light emitting elements from overlapping. It should be noted that the above-mentioned suitable cathode voltage can be selected according to the differences in structure and efficiency of organic light emitting elements of different colors.

In some examples, the cathode of each of the plurality of light emitting elements may be formed by using a patterning process. In this way, on the one hand, the cathodes of the light emitting elements can be independent cathodes, rather than all the light emitting elements sharing one cathode; on the other hand, the display substrate can avoid the problem of low manufacturing precision caused by the fine metal mask (FMM) process, thus the resolution is further improved. Similarly, the light emitting layer of the light emitting element may also be formed by a patterning process. Of course, the embodiments of the present disclosure include but are not limited to this, and the cathodes and the light emitting layers of the light emitting elements can also be formed by an evaporation process. It should be noted that the above-mentioned patterning process may include a film forming process, an exposure process, a development process and an etching process.

In some examples, the light emitting elements may be organic light emitting elements, that is, the light emitting layers of the light emitting elements are organic light emitting layers. In addition, the above-mentioned light emitting layers do not only include the film layers that directly emit light, they also include functional film layers for assisting light emission, such as hole injection layers, hole transport layers, electron injection layers, and electron transport layers.

In some examples, the cathodes in the above-mentioned light emitting elements can be made of a material with high conductivity and low work function, for example, the cathodes can be made of a metal material. For example, the anodes in the above-mentioned light emitting elements may be made of a transparent conductive material having a high work function.

For example, the cathodes in the above-mentioned light emitting elements can be made of metal materials, such as any one or more of magnesium (Mg), silver (Ag), copper (Cu), aluminum (Al), titanium (Ti) and molybdenum (Mo), or alloy materials of the above metals, such as aluminum-neodymium alloy (AlNd) or molybdenum-niobium alloy (MoNb), the cathode can be a single-layer structure or a multi-layer composite structure, such as Ti/Al/Ti, etc., or, can be a stacked structure formed by metal and transparent conductive materials, such as reflective materials such as ITO/Ag/ITO, Mo/AlNd/ITO and so on.

For example, the anodes in the above-mentioned light emitting elements can be made of a transparent conductive material, such as indium tin oxide (ITO), or, a multilayer composite structure of metal and transparent conductive material.

In some examples, as illustrated by FIG. 1A, the display substrate 100 further includes a plurality of pixel driving circuits 170, which are located at a side of the planarization layer 130 close to the base substrate 110; the plurality of pixel driving circuits 170 are arranged in one-to-one correspondence with the plurality of light emitting elements 150, an anode 152 of each of the plurality of light emitting elements 150 is electrically connected with an output end of its corresponding pixel driving circuit 170. The pixel driving circuits 170 are configured to apply a driving voltage or a driving current to the anodes 152, thus the pixel driving circuits 170 cooperate with cathode voltages on their cathodes to drive the light emitting elements to emit light.

In some examples, the pixel driving circuits may include a plurality of thin film transistors and at least one capacitor; thus each of the pixel driving circuits includes at least one conductive layer, such as a gate layer, and a source-drain electrode layer. In this case, since the pixel driving circuits and the cathode lines are located between the base substrate and the planarization layer, each of the cathode lines may include a same conductive layer as a conductive layer in the corresponding pixel driving circuit. That is, each of the cathode lines can be arranged in a same layer as part of a conductive structure in the corresponding pixel driving circuit, thus, a mask process is saved and the cost is reduced.

It is worth noting that the cathode lines mentioned above are different from a power line that provides a power supply voltage to one of the pixel driving circuits or a data line that provides a data signal to one of the pixel driving circuits; the power line and the data line are connected with the corresponding pixel driving circuit, while the cathode line is not connected with the pixel driving circuit.

In some examples, as described above, other film layers are arranged between the planarization layer and the base substrate. These other film layers may include film layers in the pixel driving circuit (for example, including thin film transistors, storage capacitors and other structures), film layers where data lines, gate lines, power signal lines, reset power signal lines, reset control signal lines, light emitting control signal lines, etc., are located, or insulating layers such as gate insulating layers, interlayer insulating layers, and passivation layers.

In some examples, the base substrate may be made of one or more materials selected from the group consisting of glass, polyimide, polycarbonate, polyacrylate, polyetherimide, and polyethersulfone, and the present embodiment includes but is not limited to this.

In some examples, the material of the pixel definition layer may include an organic material, such as polyimide, acryl, or polyethylene terephthalate.

In some examples, the material of the planarization layer may be an organic material, such as one or a combination of resin, acrylic, polyethylene terephthalate, polyimide, polyamide, polycarbonate, and epoxy resin, etc.

In some examples, as illustrated by FIG. 1A, each of the plurality of conductive isolation columns 160 is at least partially located at a side of the pixel definition layer 140 away from the base substrate 110, and each of the plurality of conductive isolation columns 160 is electrically connected with one cathode line 120 through a via hole penetrating through both the pixel definition layer 140 and the planarization layer 130.

In some examples, as illustrated by FIG. 1A, each of the plurality of conductive isolation columns 160 is partially located in a via hole penetrating through both the pixel definition layer 140 and the planarization layer 130. In this way, on the one hand, the manufacturing process can be simplified, and on the other hand, the formed conductive isolation columns can be more stable and less prone to breakage.

In some examples, each of the plurality of conductive isolation columns may be a single conductive layer or a stack of multiple conductive layers.

For example, as illustrated by FIG. 1A, each of the plurality of conductive isolation columns 160 may include a first isolation conductive layer 161, a second isolation conductive layer 162, and a third isolation conductive layer 163 which are stacked. Due to different etching rates of different materials, the conductive isolation columns 160 may have a dumbbell shape (or an I-shape) in a direction perpendicular to the base substrate 110, that is, dimensions of the first isolation conductive layer 161 and the third isolation conductive layer 163 in a direction parallel to the base substrate 110 are greater than a dimension of the second isolation conductive layer 162 in the direction.

For example, as illustrated by FIG. 1A, the cathode 156 of each of the light emitting elements 150 is overlapped with a lateral surface of a corresponding conductive isolation column 160, thereby is electrically connected with the conductive isolation column 160. With such arrangement, since an area of the lateral surface of the corresponding conductive isolation column is relatively large, a stable and reliable electrical connection can be formed between the cathode and the corresponding conductive isolation column. On the other hand, the conductive isolation column can improve the stability of the electrical connection between the cathode and the corresponding conductive isolation column by increasing a height instead of increasing an area of an orthographic projection of the conductive isolation column on the base substrate, thus an area occupied by the corresponding conductive isolation column can be reduced, and an aperture ratio can be improved. In addition, the conductive isolation columns themselves can also play a certain isolation role to prevent cathodes of adjacent light emitting elements from overlapping.

In some examples, as illustrated by FIG. 1A, each of the plurality of conductive isolation columns 160 may include a first isolation conductive layer 161, a second isolation conductive layer 162, and a third isolation conductive layer 163 that are stacked. At this time, a light emitting layer 154 of one of the light emitting elements 150 is spaced apart from a second isolation conductive layer 162 of the corresponding conductive isolation column 160, thus a cathode 156 of the light emitting element 150 is overlapped with a side of a second isolation conductive layer 162 of the corresponding conductive isolation column 160, and is arranged in contact with a top surface of the first isolation conductive layer 161 in the above-mentioned space. Therefore, the cathode of the light emitting element is overlapped with the first isolation conductive layer and the second isolation conductive layer respectively, which can further enhance the stability of the electrical connection.

In some examples, as illustrated by FIG. 1A, the light emitting layer 154 of each of the light emitting elements 150 is overlapped with an edge of the first isolation conductive layer 161 of the corresponding conductive isolation column 160.

In some examples, as illustrated by FIG. 1A, a cathode 156 of each of the plurality of light emitting elements 150 is arranged in direct contact with a lateral surface of the corresponding conductive isolation column 160, thereby is electrically connected with the corresponding conductive isolation column 160. Of course, the embodiments of the present disclosure include but are not limited to this, other conductive structures may also be arranged between a cathode of each of the plurality of light emitting elements and a lateral surface of the corresponding conductive isolation column. FIG. 1B is a schematic diagram of an overlapping between a cathode of another light emitting element and the corresponding conductive isolation column provided by an embodiment of the present disclosure. As illustrated by FIG. 1B, a cathode 156 of each of a plurality of light emitting elements 150 is connected with a lateral surface of a corresponding conductive isolation column 160 through a conductive structure 260. In this way, by arranging the above-mentioned conductive structure, on the one hand, a material having good bonding strength with both the cathode and the corresponding conductive isolation column can be used to manufacture the conductive structure, thus the stability of the connection is further enhanced; on the other hand, suitable materials may also be used to reduce a contact resistance between the cathode and the corresponding conductive isolation column.

In some examples, as illustrated by FIG. 1A, sizes of the conductive isolation columns 160 in a direction perpendicular to the base substrate 110 are larger than sizes of the light emitting elements 150 in the direction perpendicular to the base substrate 110.

In some examples, as illustrated by FIG. 1A, the sizes of the conductive isolation columns 160 in the direction perpendicular to the base substrate 110 is greater than twice the sizes of the light emitting elements 150 in the direction perpendicular to the base substrate 110.

In some examples, as illustrated by FIG. 1A, due to the isolation effect of the conductive isolation columns 160, the light emitting layers 154 and the cathodes 156 of the light emitting elements 150 may be partially located on the conductive isolation columns 160, that is, a side of the conductive isolation columns 160 away from the base substrate 110

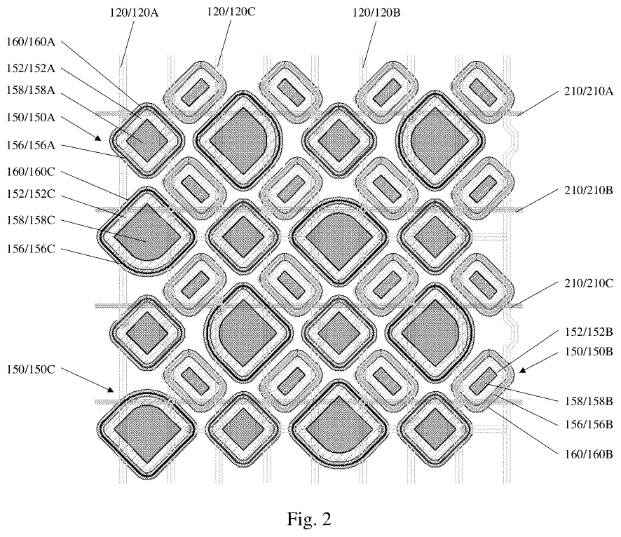

FIG. 2 is a planar schematic diagram of a display substrate provided by an embodiment of the present disclosure. As illustrated by FIG. 1A and FIG. 2, the plurality of light emitting elements 150 include first light emitting elements 150A, second light emitting elements 150B, and third light emitting elements 150C; each of the first light emitting elements 150A includes a first anode 152A, a first light emitting layer 154A and a first cathode 156A, each of the second light emitting elements 150B includes a second anode 152B, a second light emitting layer 154B, and a second cathode 156B, and each of the third light emitting elements 150C includes a third anode 152C, a third light emitting layer 154C and a third cathode 156C; the first anode 152A and the first cathode 156A are configured to drive the first light emitting layer 154A to emit light of a first color, the second anode 152B and the second cathode 156B are configured to drive the second light emitting layer 154B to emit light of a second color, and the third anode 152C and the third cathode 156C are configured to drive the third light emitting layer 154 °C to emit light of a third color. In this way, the display substrate can achieve full-color display.

For example, the first color may be red, the second color may be green, and the third color may be blue. Of course, the embodiments of the present disclosure include but are not limited to this, and the first color, the second color, and the third color may also be other colors.

In some examples, as illustrated by FIG. 1A and FIG. 2, the first cathode 156A, the second cathode 156B, and the third cathode 156C are independent with each other, or the first cathode 156A, the second cathode 156B and the third cathode 156C are spaced apart from each other.

In some examples, as illustrated by FIG. 1A and FIG. 2, the plurality of cathode lines 120 include first cathode lines 120A, second cathode lines 120B, and third cathode lines 120C, and the plurality of conductive isolation columns 160 include first conductive isolation columns 160A, second conductive isolation columns 160B, and third conductive isolation columns 160C.

As illustrated by FIG. 1A and FIG. 2, the first conductive isolation column 160A is electrically connected with a first cathode line 120A and a first cathode 156A of the corresponding first light emitting element 150A, respectively, so that a cathode voltage on the first cathode line 120A can be applied to the first cathode 156A of the corresponding first light emitting element 150A; the second conductive isolation column 160B is electrically connected with a second cathode line 120B and a second cathode 156B of the corresponding second light emitting element 150B, respectively, thus a cathode voltage on the second cathode line 120B can be applied to the second cathode 156B of the corresponding second light emitting element 150B; the third conductive isolation column 160C is electrically connected to a third cathode line 120C and a third cathode 156C of the corresponding third light emitting element 150C, respectively, thus a cathode voltage on the third cathode line 120C can be applied to the third cathode 156C of the corresponding third light emitting element 150C. In this way, different cathode voltages can be applied to different cathode lines for light emitting elements of different colors, so that each of the light emitting elements uses a suitable cathode voltage, avoiding redundant voltage and redundant power consumption, thus the overall power consumption of the display substrate is reduced. It should be noted that the above-mentioned suitable cathode voltage can be selected according to differences in structure and efficiency of the organic light emitting elements of different colors.

In some examples, the first cathode lines 120A, the second cathode lines 120B, and the third cathode lines 120C are configured to be loaded with different cathode voltages. For example, the first cathode lines 120A, the second cathode lines 120B, and the third cathode lines 120C may be connected with different conductive ends in a binding region of the display substrate, so as to be loaded with different cathode voltages.

In some examples, as illustrated by FIG. 1A and FIG. 2, an orthographic projection of a first conductive isolation column 160A on the base substrate 110 is located at a periphery of an orthographic projection of the corresponding first light emitting element 150A on the base substrate 110. In this way, the display substrate can use spacing regions between the first light emitting element and other light emitting elements to set the first conductive isolation column. Therefore, the aperture ratio of the display substrate can be improved. In addition, the display substrate can also utilize an isolation effect of the first conductive isolation column, to reduce a risk of cathode overlap between the corresponding first light emitting element and other light emitting elements.

In some examples, as illustrated by FIG. 1A and FIG. 2, an orthographic projection of a second conductive isolation column 160B on the base substrate 110 is located at a periphery of an orthographic projection of the corresponding second light emitting element 150B on the base substrate 110. In this way, the display substrate can use a spacing region between the corresponding second light emitting element and other light emitting elements to set the second conductive isolation column, thus the aperture ratio of the display substrate can be improved. In addition, the display substrate can also utilize an isolation effect of the second conductive isolation column, to reduce a risk of cathode overlap between the corresponding second light emitting element and other light emitting elements.

In some examples, as illustrated by FIG. 1A and FIG. 2, an orthographic projection of a third conductive spacer column 160C on the base substrate 110 is located at a periphery of an orthographic projection of the corresponding third light emitting element 150C on the base substrate 110. In this way, the display substrate can use a spacing region between the corresponding third light emitting element and other light emitting elements to set the third conductive isolation column, thus the aperture ratio of the display substrate can be improved. In addition, the display substrate can also utilize an isolation effect of the third conductive isolation column, to reduce a risk of cathode overlap between the corresponding third light emitting element and other light emitting elements.

In some examples, as illustrated by FIG. 1A and FIG. 2, the display substrate 100 further includes a first temporary encapsulation layer 180A and a second temporary encapsulation layer 180B; the first temporary encapsulation layer 180A is located at a side of the first light emitting element 150A away from the base substrate 110; the second temporary encapsulation layer 180B is located at a side of the second light emitting element 150B away from the base substrate 110. In this way, after forming a first cathode 156A, the first temporary encapsulation layer 180A timely encapsulates the corresponding first light emitting element 150A to prevent the corresponding first light emitting element 150A from being corroded by water and oxygen in subsequent processes; after forming a second cathode 156B, the second temporary encapsulation layer 180B timely encapsulates the corresponding first light emitting element 150B to prevent the corresponding first light emitting element 150B from being corroded by water and oxygen in subsequent processes.

In some examples, as illustrated by FIG. 1A and FIG. 2, the display substrate 100 further includes a third temporary encapsulation layer 180C, which is located at a side of the corresponding third light emitting element 150C away from the base substrate 110, thus the third light emitting element 150C is prevented from being corroded by water and oxygen in subsequent processes.

It is worth noting that since cathodes of the light emitting elements of different colors in the present embodiment are not formed in one process step, by forming the above-mentioned temporary encapsulation layer, the process of the present embodiment can be adapted to prevent water and oxygen from corroding the formed light emitting elements.

In some examples, as illustrated by FIG. 1A and FIG. 2, the first temporary encapsulation layer 180A, the second temporary encapsulation layer 180B and the third temporary encapsulation layer 180C are independent with each other, and are spaced apart from each other. That is, the first temporary encapsulation layer, the second temporary encapsulation layer and the third temporary encapsulation layer are not encapsulation layers in a common display substrate, but different encapsulation structures that are independently arranged and manufactured.

In some examples, as illustrated by FIG. 1A and FIG. 2, the display substrate 100 further includes an encapsulation layer 190 located at a side of the first temporary encapsulation layer 180A, the second temporary encapsulation layer 180B and the third temporary encapsulation layer 180C away from the base substrate 110. The encapsulation layer 190 is equivalent to an encapsulation layer in a general display substrate. In addition, since the display substrate adopts two encapsulation structures (temporary encapsulation layer and encapsulation layer), the display substrate has a better encapsulation effect and a better effect of waterproofing and preventing oxygen corrosion.

In some examples, as illustrated by FIG. 1A and FIG. 2, an orthographic projection of each of the plurality of conductive isolation columns 160 on the base substrate 110 surrounds an orthographic projection of the corresponding light emitting element 150 on the base substrate 110. In this way, on the one hand, a cathode 156 of each of the light emitting elements 150 can be electrically connected with the surrounding conductive isolation column 160, thus a more stable electrical connection can be achieved; on the other hand, each of the plurality of conductive isolation columns 160 can also achieve a better isolation effect.

For example, as illustrated by FIG. 1A and FIG. 2, an orthographic projection of each of the first conductive isolation columns 160A on the base substrate 110 surrounds an orthographic projection of the corresponding first light emitting element 150A on the base substrate 110. In this way, on one hand, a cathode 156A of the corresponding first light emitting element 150A can be electrically connected with the surrounding first conductive isolation column 160A, thus a more stable electrical connection can be achieved; on the other hand, the first conductive isolation column 160A can also achieve a better isolation effect.

For example, as illustrated by FIG. 1A and FIG. 2, an orthographic projection of each of the second conductive isolation columns 160B on the base substrate 110 surrounds an orthographic projection of the corresponding second light emitting element 150B on the base substrate 110. In this way, on one hand, a cathode 156B of the corresponding second light emitting element 150B can be electrically connected with the surrounding second conductive isolation column 160B, thus a more stable electrical connection can be achieved; on the other hand, the second conductive isolation column 160B can also achieve a better isolation effect.

For example, as illustrated by FIG. 1A and FIG. 2, an orthographic projection of each of the third conductive spacer columns 160C on the base substrate 110 surrounds an orthographic projection of the corresponding third light emitting element 150C on the base substrate 110. In this way, on one hand, a cathode 156C of the corresponding third light emitting element 150C can be electrically connected with the surrounding third conductive isolation column 160C, thus a more stable electrical connection can be achieved; on the other hand, the third conductive isolation column 160C can also achieve a better isolation effect.

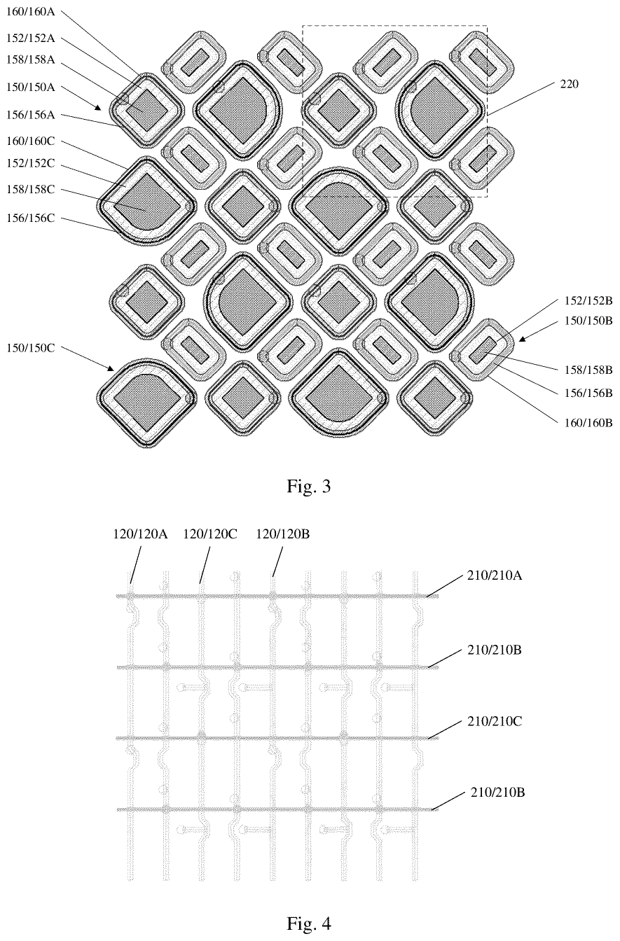

FIG. 3 is a schematic diagram of stacking of light emitting elements and conductive isolation columns in a display substrate provided by an embodiment of the present disclosure. As illustrated by FIG. 3, an orthographic projection of a first conductive isolation column 160A on the base substrate 110 surrounds an orthographic projection of the corresponding first light emitting element 150A on the base substrate 110, a first cathode 156A of the corresponding first light emitting element 150A is overlapped with a lateral surface of a first conductive isolation column 160A surrounding the corresponding first light emitting element 150A (for example, a lateral surface close to the corresponding first light emitting element), and a contact surface formed by the overlapping can be annular.

In some examples, as illustrated by FIG. 3, an orthographic projection of a second conductive isolation column 160B on the base substrate 110 surrounds an orthographic projection of the corresponding second light emitting element 150B on the base substrate 110, a second cathode 156B of the corresponding second light emitting element 150B is overlapped with a lateral surface of a second conductive isolation column 160B surrounding the second light emitting element 150B (for example, a lateral surface close to the second light emitting element), and a contact surface formed by the overlap can be annular.

In some examples, as illustrated by FIG. 3, an orthographic projection of the third conductive isolation column 160C on the base substrate 110 surrounds an orthographic projection of the corresponding third light emitting element 150C on the base substrate 110, a third cathode 156C of the corresponding third light emitting element 150C is overlapped with a lateral surface of a third conductive isolation column 160C surrounding the third light emitting element 150C (for example, a lateral surface close to the corresponding third light emitting element), and a contact surface formed by the overlap can be annular.

In some examples, as illustrated by FIG. 3, each of the first light emitting elements 150A further includes a first opening 158A located in the pixel definition layer 140, a first anode 152A is located at a side of the pixel definition layer 140 close to the base substrate 110, and is exposed by the first opening 158A, and the first light emitting layer 154A is at least partially located in the first opening 158A, to contact with the first anode 152A. In this way, an effective display region of the first light emitting element is mainly defined by the first opening.

In some examples, as illustrated by FIG. 3, each of the second light emitting elements 150B further includes a second opening 158B located in the pixel definition layer 140, a second anode 152B is located at a side of the pixel definition layer 140 close to the base substrate 110, and is exposed by the second opening 158B, and the second light emitting layer 154B is at least partially located in the second opening 158B to contact with the second anode 152B. In this way, an effective display region of the second light emitting element is mainly defined by the second opening.

In some examples, as illustrated by FIG. 3, each of the third light emitting elements 150B further includes a third opening 158C located in the pixel definition layer 140, a third anode 152C is located at a side of the pixel definition layer 140 close to the base substrate 110, and is exposed by the third opening 158C, and the third light emitting layer 154C is at least partially located in the third opening 158C, to contact with the third anode 152C. In this way, an effective display region of the third light emitting element is mainly defined by the third opening.

In some examples, as illustrated by FIG. 3, the first anode 152A, the second anode 152B, and the third anode 152C may all be located in an anode layer between the planarization layer 130 and the pixel definition layer 140.

In some examples, as illustrated by FIG. 3, an orthographic projection of a first conductive isolation column 160A on the base substrate 110 surrounds an orthographic projection of the first opening 158A of the first light emitting element 150A on the base substrate 110; an orthographic projection of a second conductive isolation column 160B on the base substrate 110 surrounds an orthographic projection of the second opening 158B of the second light emitting element 150B on the base substrate 110; and an orthographic projection of the third conductive isolation column 160C on the base substrate 110 surrounds an orthographic projection of the third opening 158C of the third light emitting element 150C on the base substrate 110.

In some examples, as illustrated by FIG. 3, an arrangement structure of the plurality of light emitting elements 150 may adopt a GGRB arrangement structure. That is, the plurality of light emitting elements 150 may be arranged to include a plurality of light emitting element groups 220, each of the plurality of light emitting element groups 220 includes one first light emitting element 150A, two second light emitting elements 150B, and one third light emitting element 150C. In each of the plurality of light emitting element groups 220, the first light emitting element 150A and the third light emitting element 150 °C are arranged along a first direction, and the two second light emitting elements 150B are arranged along a second direction.

In some examples, as illustrated by FIG. 3, in each of the plurality of light emitting element groups 220, the first conductive isolation column 160A corresponding to the first light emitting element 150A is connected with a first cathode line 160A through a via hole; the second conductive isolation columns 160B corresponding to the two second light emitting elements 150B are connected with a same second cathode line 160B through via holes; and the third conductive isolation column 160C corresponding to the third light emitting element 150C is connected with a third cathode line 160C through a via hole.

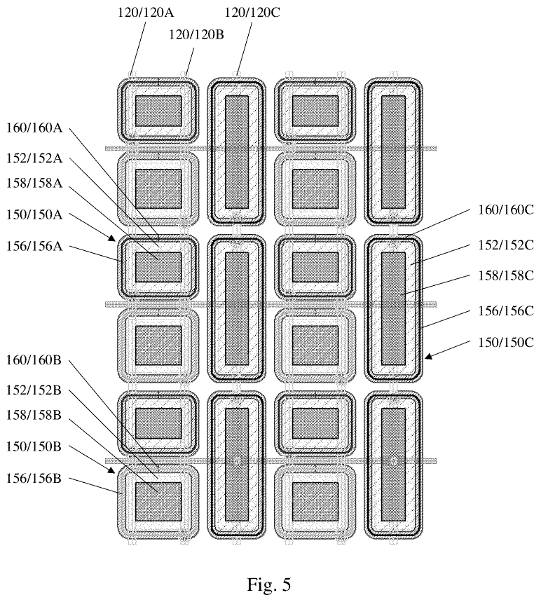

FIG. 4 is a schematic diagram of a plurality of cathode lines in a display substrate provided by an embodiment of the present disclosure. As illustrated by FIG. 4, the display substrate 100 further includes a plurality of cathode connection lines 210, each of the plurality of cathode connection lines 210 is electrically connected with at least two cathode lines 120 among the plurality of cathode lines 120, thus resistance and voltage drop of the cathode lines can be effectively reduced.

In some examples, as illustrated by FIG. 4, each of the plurality of cathode connection lines 210 is located in a first conductive layer 201, and extends along the first direction, each of the plurality of cathode lines 120 is located in a second conductive layer 202, and extends along the second direction, and the first direction is intersected with the second direction. In this way, each of the plurality of cathode connection lines facilitates electrical connections of cathode lines that need to be connected.

For example, the first direction and the second direction may be perpendicular to each other. Of course, the embodiments of the present disclosure include but are not limited to this.

In some examples, the first conductive layer may be a conductive layer included in a pixel driving circuit, such as a gate layer, a source-drain electrode layer, etc.; the second conductive layer may be another conductive layer included in the pixel driving circuit, such as a gate layer, a source-drain electrode layer, etc. In this case, since the pixel driving circuit, the cathode connection lines and the cathode lines are all located between the base substrate and the planarization layer, the cathode connection lines and the cathode lines may include a same conductive layer as a conductive layer in the pixel driving circuit, thus a mask process is saved and the cost is reduced.

In some examples, as illustrated by FIG. 4, the plurality of cathode lines 120 include a plurality of first cathode lines 120A, a plurality of second cathode lines 120B, and a plurality of third cathode lines 120C, the plurality of cathode connection lines 210 include first cathode connection lines 210A, second cathode connection lines 210B and third cathode connection lines 210C; two first cathode lines 120A adjacent to each other in the first direction are electrically connected with a same first cathode connection line 210A, two second cathode lines 120B adjacent to each other in the first direction are electrically connected with a same second cathode connection line 210B, and two third cathode lines 120C adjacent to each other in the first direction are electrically connected with a same third cathode connection line 120C. In this way, the first cathode connection lines 210A can effectively reduce resistance and voltage drop of the first cathode lines 120A and maintain uniformity of the entire display substrate; the second cathode connection lines 210B can effectively reduce resistance and voltage drop of the second cathode lines 120B and maintain the uniformity of the entire display substrate; and the third cathode connection lines 210C can effectively reduce resistance and voltage drop of the third cathode lines 120C and maintain the uniformity of the entire display substrate.

In some examples, as illustrated by FIG. 4, the first cathode connection lines 210A, the second cathode connection lines 210B, and the third cathode connection lines 210C are arranged along the second direction.

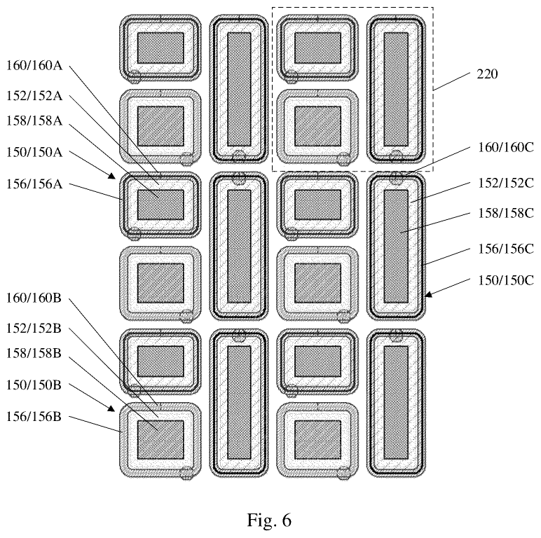

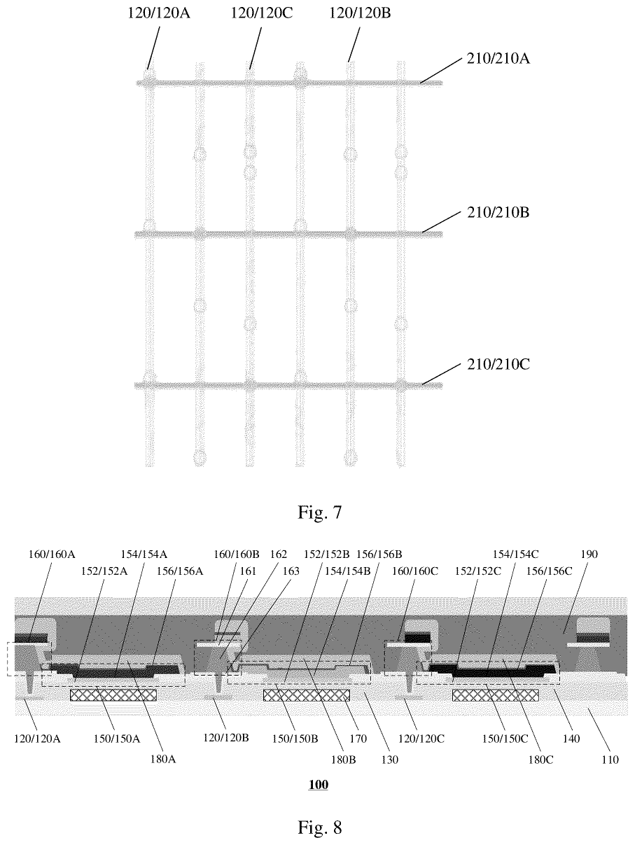

FIG. 5 is a planar schematic diagram of another display substrate provided by an embodiment of the present disclosure; FIG. 6 is a schematic diagram of stacking of light emitting elements and conductive isolation columns in another display substrate provided by an embodiment of the present disclosure; and FIG. 7 is a schematic diagram of cathode lines in another display substrate provided by an embodiment of the present disclosure.

Different from the display substrate shown in FIG. 2, as illustrated by FIG. 5, FIG. 6 and FIG. 7, an arrangement structure of the plurality of light emitting elements 150 may adopt a real-RGB arrangement structure. That is, the plurality of light emitting elements 150 may be arranged to include a plurality of light emitting element groups 220, each of the plurality of light emitting element groups 220 includes a first light emitting element 150A, a second light emitting element 150B, and a third light emitting element 150C. In each of the plurality of light emitting element groups 220, the first light emitting element 150A and the second light emitting element 150B are arranged along the second direction, and the first light emitting element 150A and the third light emitting element 150C are arranged along the first direction.

In some examples, as illustrated by FIG. 5, FIG. 6, and FIG. 7, in each of the plurality of light emitting element groups 220, a first conductive isolation column 160A corresponding to the first light emitting element 150A is connected with a first cathode line 160A through a via hole; a second conductive isolation column 160B corresponding to the second light emitting element 150B is connected with a second cathode line 160B through a via hole; and a third conductive isolation column 160C corresponding to the third light emitting element 150C is connected with a third cathode line 160C through a via hole.

In some examples, as illustrated by FIG. 5, FIG. 6, and FIG. 7, since the first light emitting elements 150A and the second light emitting elements 150B arranged in the second direction need to be connected with two different cathode lines 120, and sizes of the first light emitting elements 150A and the second light emitting elements 150B in the first direction are larger than sizes of the third light emitting elements 150C in the first direction.

FIG. 8 is a structural schematic diagram of a display substrate provided by an embodiment of the present disclosure. As illustrated by FIG. 8, the display substrate 100 includes a base substrate 110, a plurality of cathode lines 120, a planarization layer 130, a pixel definition layer 140, and a plurality of light emitting elements 150; the plurality of cathode lines 120 are located on the base substrate 110; the planarization layer 130 is located at a side of the plurality of cathode lines 120 away from the base substrate 110; and the pixel definition layer 140 is located at a side of the planarization layer 130 away from the plurality of cathode lines 120.

For example, as illustrated by FIG. 8, each of the plurality of cathode lines 120 is configured to provide a cathode voltage to a cathode of a light emitting element to drive the light emitting element to emit light; and the plurality of cathode lines may provide different cathode voltages, that is, the cathode voltages on the plurality of cathode lines may include a plurality of different cathode voltages.

As illustrated by FIG. 8, the display substrate 100 further includes a plurality of conductive isolation columns 160 arranged in one-to-one correspondence with the plurality of light emitting elements 150, each of the plurality of conductive isolation columns 160 is electrically connected with a cathode line 120, each of the plurality of light emitting element 150 includes an anode 152, a light emitting layer 154, and a cathode 156, and the cathode 156 of the each of the plurality of light emitting elements 150 is electrically connected with the corresponding conductive isolation column 160. Different from the display substrate shown in FIG. 1A, only one conductive isolation column 160 is arranged between adjacent light emitting elements 150.

In the display substrate provided by the embodiment of the present disclosure, the cathode of each of the plurality of light emitting elements in the display substrate can be connected with a cathode line under the planarization layer through a conductive isolation column, thus a cathode voltage can be applied to the cathode of each of the plurality of light emitting elements through the cathode line under the planarization layer. With such arrangement, the display substrate can realize that different light emitting elements use independent cathodes and apply different cathode voltages, which enables that each of the plurality of light emitting elements use a suitable cathode voltage, avoids redundant voltage and redundant power consumption, and thus reduces the overall power consumption of the display substrate. On the other hand, the conductive isolation columns themselves can also play a certain isolation role to prevent the cathodes of adjacent light emitting elements from overlapping. Furthermore, since only one conductive isolation column is arranged between adjacent light emitting elements, the display substrate can further reduce an interval width between adjacent light emitting elements, thus the aperture ratio and resolution are improved. It should be noted that the above-mentioned suitable cathode voltage can be selected according to differences in structure and efficiency of organic light emitting elements of different colors.

In some examples, as illustrated by FIG. 8, the cathode 156 of each of the plurality of light emitting elements 150 is connected only with a conductive isolation column 160 located on one side of the light emitting element 150, rather than being connected to all the conductive isolation columns 160 on both sides or around the light emitting element 150.

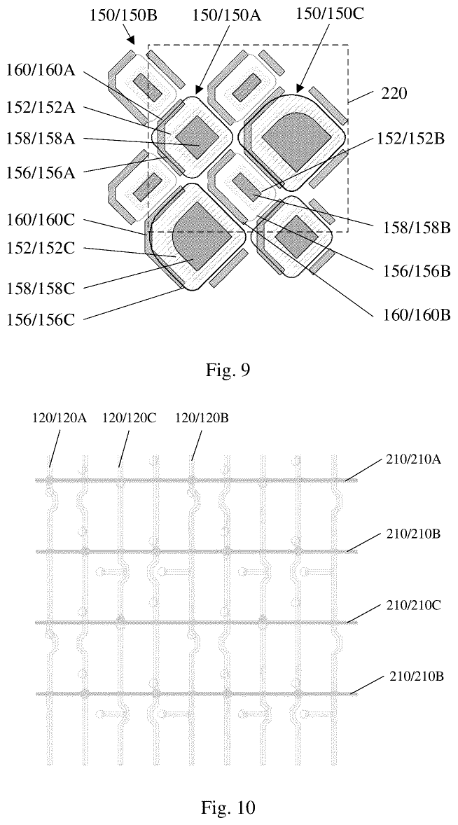

FIG. 9 is a schematic diagram of stacking of light emitting elements and conductive isolation columns in another display substrate provided by an embodiment of the present disclosure; and FIG. 10 is a schematic diagram of cathode lines of another display substrate provided by an embodiment of the present disclosure. As illustrated by FIG. 8, FIG. 9 and FIG. 10, the plurality of light emitting elements 150 include first light emitting elements 150A, second light emitting elements 150B and third light emitting elements 150C; each of the first light emitting elements 150A includes a first anode 152A, a first light emitting layer 154A and a first cathode 156A, each of the second light emitting elements 150B includes a second anode 152B, a second light emitting layer 154B, and a second cathode 156B, each of the third light emitting elements 150C includes a third anode 152C, a third light emitting layer 154C and a third cathode 156C; the first anode 152A and the first cathode 156A are configured to drive the first light emitting layer 154A to emit light of a first color, the second anode 152B and the second cathode 156B are configured to drive the second light emitting layer 154B to emit light of a second color, and the third anode 152C and the third cathode 156C are configured to drive the third light emitting layer 154 °C to emit light of a third color. In this way, the display substrate can achieve full-color display.

For example, the first color may be red, the second color may be green, and the third color may be blue. Of course, the embodiments of the present disclosure include but are not limited to this, and the first color, the second color and the third color may also be other colors.

In some examples, as illustrated by FIG. 8, FIG. 9, and FIG. 10, the first cathode 156A, the second cathode 156B, and the third cathode 156C are independent with each other, or the first cathode 156A, the second cathode 156B and the third cathode 156C are spaced apart from each other.

In some examples, as illustrated by FIG. 8, FIG. 9, and FIG. 10, the plurality of cathode lines 120 include first cathode lines 120A, second cathode lines 120B, and third cathode lines 120C, and the plurality of conductive isolation columns 160 include first conductive isolation columns 160A, second conductive isolation columns 160B, and third conductive isolation columns 160C.

As illustrated by FIG. 8, FIG. 9 and FIG. 10, a first conductive isolation column 160A is electrically connected with a first cathode line 120A and a first cathode 156A of a first light emitting element 150A, respectively, thus a cathode voltage on the first cathode line 120A can be applied to the first cathode 156A of the first light emitting element 150A; a second conductive isolation column 160B is electrically connected with a second cathode line 120B and a second cathode 156B of a second light emitting element 150B, respectively, thus a cathode voltage on the second cathode line 120B can be applied to the second cathode 156B of the second light emitting element 150B; a third conductive isolation column 160C is electrically connected with a third cathode line 120C and a third cathode 156C of a third light emitting element 150C, respectively, thus a cathode voltage on the third cathode line 120C can be applied to the third cathode 156C of the third light emitting element 150C. In this way, different colors of light emitting elements can apply different cathode voltages through different cathode lines, can enable each of the light emitting elements to use a suitable cathode voltage, avoiding redundant voltage and redundant power consumption, thereby reducing the overall power consumption of the display substrate. It should be noted that the above-mentioned suitable cathode voltage can be selected according to the differences in structure and efficiency of organic light emitting elements of different colors.

In some examples, the first cathode lines 120A, the second cathode lines 120B, and the third cathode lines 120C are configured to be loaded with different cathode voltages. For example, the first cathode lines 120A, the second cathode lines 120B, and the third cathode lines 120C may be connected to different conductive ends in a binding region of the display substrate, so as to be loaded with different cathode voltages.

In some examples, as illustrated by FIG. 8, FIG. 9, and FIG. 10, an orthographic projection of each of the first conductive isolation columns 160A on the base substrate 110 is located around an orthographic projection of the corresponding first light emitting element 150A on the base substrate 110. In this way, the display substrate can use a spacing region between the corresponding first light emitting element and other light emitting elements to set the first conductive isolation column, thus the aperture ratio of the display substrate can be improved. In addition, the display substrate can also utilize the isolation effect of the first conductive isolation column, to reduce a risk of cathode overlap between the corresponding first light emitting element and other light emitting elements.

In some examples, as illustrated by FIG. 8, FIG. 9, and FIG. 10, an orthographic projection of each of the second conductive isolation columns 160B on the base substrate 110 is located around an orthographic projection of the corresponding second light emitting element 150B on the base substrate 110. In this way, the display substrate can use a spacing region between the corresponding second light emitting element and other light emitting elements to set the second conductive isolation column, thus the aperture ratio of the display substrate can be improved. In addition, the display substrate can also utilize an isolation effect of the second conductive isolation column, to reduce a risk of cathode overlap between the corresponding second light emitting element and other light emitting elements.

In some examples, as illustrated by FIG. 8, FIG. 9, and FIG. 10, an orthographic projection of each of the third conductive isolation columns 160C on the base substrate 110 is located around an orthographic projection of the corresponding third light emitting element 150C on the base substrate 110. In this way, the display substrate can use a spacing region between the corresponding third light emitting element and other light emitting elements to set the third conductive isolation column, thus the aperture ratio of the display substrate can be improved. In addition, the display substrate can also utilize an isolation effect of the third conductive isolation column, to reduce a risk of cathode overlap between the corresponding third light emitting element and other light emitting elements.

In some examples, as illustrated by FIG. 8, FIG. 9, and FIG. 10, the orthographic projection of each of the plurality of conductive isolation columns 160 on the base substrate 110 half surrounds the orthographic projection of the corresponding light emitting element 150 on the base substrate 110. In this way, on the one hand, a cathode 156 of each of the light emitting elements 150 can be electrically connected with the surrounding conductive isolation column 160, thus a relatively stable electrical connection can be achieved, and each of the plurality of conductive isolation columns 160 can also achieve a better isolation effect. On the other hand, the display substrate can realize that only one conductive isolation column is arranged between adjacent light emitting elements 150, thus the aperture ratio and resolution can be further improved.

For example, as illustrated by FIG. 8, FIG. 9 and FIG. 10, the orthographic projection of each of the first conductive isolation columns 160A on the base substrate 110 half surrounds the orthographic projection of the corresponding first light emitting element 150A on the base substrate 110. In this configuration, other conductive isolation columns can be arranged at a position where a notch of the first conductive isolation column 160A is located.

For example, as illustrated by FIG. 8, FIG. 9 and FIG. 10, the orthographic projection of each of the second conductive isolation columns 160B on the base substrate 110 half surrounds the orthographic projection of the corresponding second light emitting element 150B on the base substrate 110. In this configuration, other conductive isolation columns can be arranged at a location where a notch of the second conductive isolation column 160B is located.

For example, as illustrated by FIG. 8, FIG. 9 and FIG. 10, the orthographic projection of each of the third conductive isolation columns 160C on the base substrate 110 half surrounds the orthographic projection of the corresponding third light emitting element 150C on the base substrate 110. In this configuration, other conductive isolation columns can be arranged at a location where a notch of the third conductive isolation column 160C is located.

In some examples, as illustrated by FIG. 9, an arrangement structure of the plurality of light emitting elements 150 may adopt a GGRB arrangement structure. That is, the plurality of light emitting elements 150 may be arranged to include a plurality of light emitting element groups 220, each of the plurality of light emitting element groups 220 includes one first light emitting element 150A, two second light emitting elements 150B, and one third light emitting element 150C. In each of the plurality of light emitting element groups 220, the first light emitting element 150A and the third light emitting element 150C are arranged along the first direction, and the two second light emitting elements 150B are arranged along the second direction.

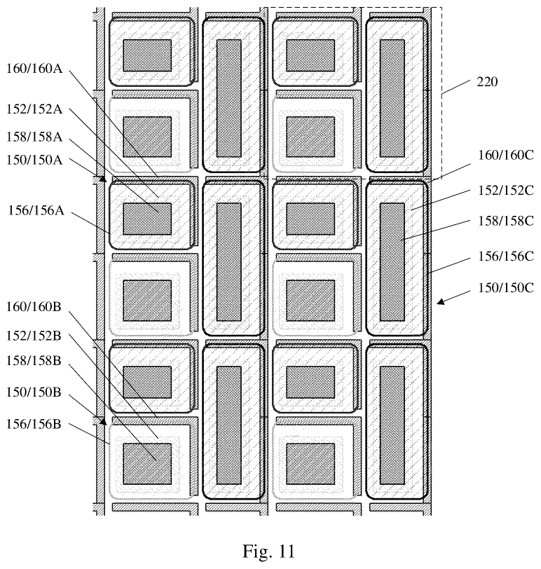

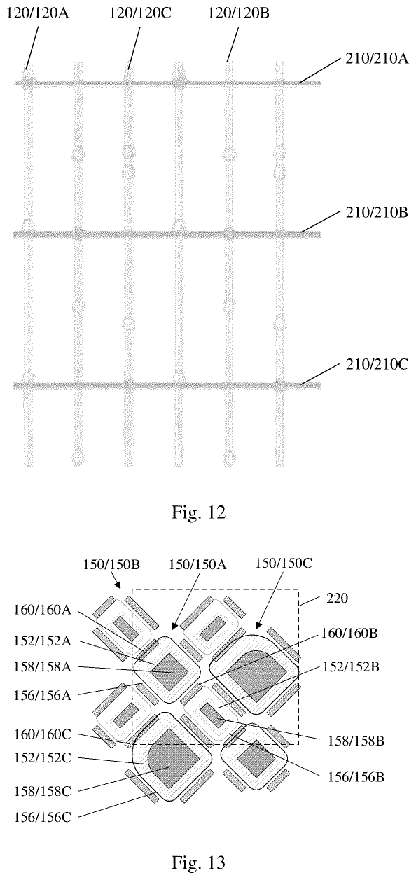

FIG. 11 is a schematic diagram of stacking of light emitting elements and conductive isolation columns in another display substrate provided by an embodiment of the present disclosure; and FIG. 12 is a schematic diagram of cathode lines of another display substrate provided by an embodiment of the present disclosure. Different from the display substrate shown in FIG. 9 and FIG. 10, as illustrated by FIG. 11 and FIG. 12, the arrangement structure of the plurality of light emitting elements 150 may adopt a real-RGB arrangement structure. That is, the plurality of light emitting elements 150 may be arranged to include a plurality of light emitting element groups 220. Each of the plurality of light emitting element groups 220 includes a first light emitting element 150A, a second light emitting element 150B, and a third light emitting element 150C. In each of the plurality of light emitting element groups 220, the first light emitting element 150A and the second light emitting element 150B are arranged along the second direction, and the first light emitting element 150A and the third light emitting element 150C are arranged along the first direction.

In some examples, as illustrated by FIG. 11 and FIG. 12, in each of the plurality of light emitting element group 220, a first conductive isolation column 160A corresponding to the first light emitting element 150A is connected with a first cathode line 160A through a via hole; a second conductive isolation column 160B corresponding to the second light emitting element 150B is connected with the second cathode line 160B through a via hole; and a third conductive isolation column 160C corresponding to the third light emitting element 150C is connected with a third cathode line 160C through a via hole.

In some examples, as illustrated by FIG. 11 and FIG. 12, since the first light emitting elements 150A and the second light emitting elements 150B arranged in the second direction need to be connected with two different cathode lines 120, sizes of the first light emitting elements 150A and the second light emitting elements 150B in the first direction are larger than sizes of the third light emitting elements 150C in the first direction.

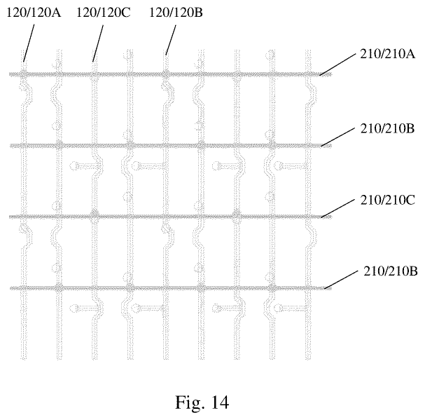

FIG. 13 is a schematic diagram of stacking light emitting elements and conductive isolation columns in another display substrate provided by an embodiment of the present disclosure; and FIG. 14 is a schematic diagram of cathode lines of another display substrate provided by an embodiment of the present disclosure. Different from the display substrate shown in FIG. 9 and FIG. 10, as illustrated by FIG. 13 and FIG. 14, an orthographic projection of each of the plurality of conductive isolation columns 160 on the base substrate 110 is located on one side of an orthographic projection of an edge of the corresponding light emitting element 150 on the base substrate 110. In this way, on the one hand, a cathode 156 of each of the light emitting elements 150 can be electrically connected to the surrounding conductive isolation column 160, thus a relatively stable electrical connection can be achieved. On the other hand, the display substrate can realize that only one conductive isolation column is arranged between adjacent light emitting elements 150, thus the aperture ratio and resolution can be further improved.

For example, as illustrated by FIG. 13 and FIG. 14, the orthographic projection of each of the first conductive solation columns 160A on the base substrate 110 is located on one side of an orthographic projection of an edge of the corresponding first light emitting element 150A on the base substrate 110. In this way, other conductive isolation columns may be arranged at other edges of the corresponding first light emitting element 150A.

For example, as illustrated by FIG. 13 and FIG. 14, the orthographic projection of each of the second conductive solation columns 160B on the base substrate 110 is located at a side of an orthographic projection of an edge of the corresponding second light emitting element 150B on the base substrate 110. In this way, other conductive isolation columns may be arranged at other edges of the corresponding second light emitting element 150B.

For example, as illustrated by FIG. 13 and FIG. 14, the orthographic projection of each of the third conductive solation columns 160C on the base substrate 110 is located on one side of an orthographic projection of an edge of the corresponding third light emitting element 150C on the base substrate 110. In this way, other conductive isolation columns may be disposed at other edges of the corresponding third light emitting element 150C.

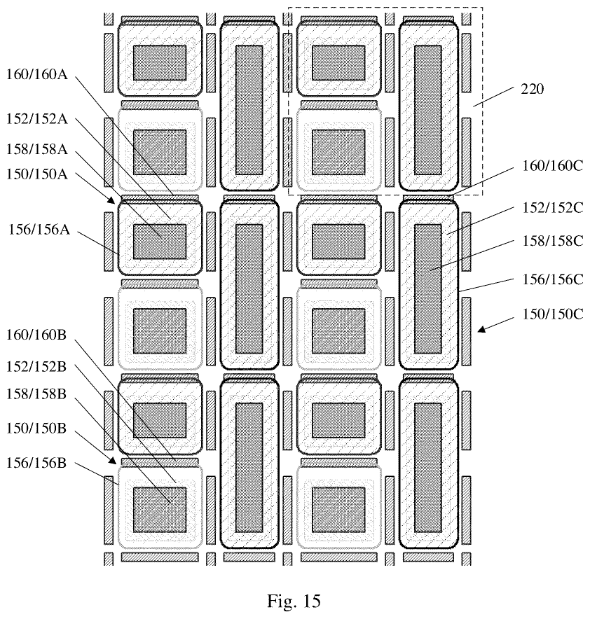

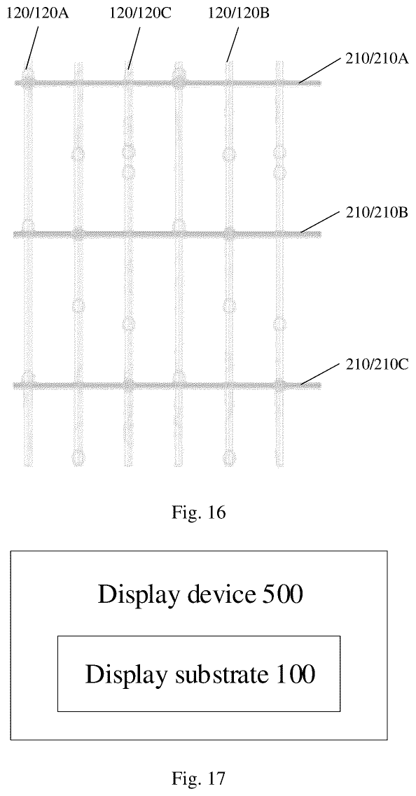

FIG. 15 is a schematic diagram of stacking of light emitting elements and conductive isolation columns in another display substrate provided in an embodiment of the present disclosure; and FIG. 16 is a schematic diagram of cathode lines of another display substrate provided by an embodiment of the present disclosure. Different from the display substrate shown in FIG. 13 and FIG. 14, as illustrated by FIG. 15 and FIG. 16, an arrangement structure of the plurality of light emitting elements 150 may adopt a real-RGB arrangement structure. That is, the plurality of light emitting elements 150 may be arranged to include a plurality of light emitting element groups 220, each of the plurality of light emitting element groups 220 includes a first light emitting element 150A, a second light emitting element 150B, and a third light emitting element 150C. In each of the plurality of light emitting element groups 220, the first light emitting element 150A and the second light emitting element 150B are arranged along the second direction, and the first light emitting element 150A and the third light emitting element 150C are arranged along the first direction.

FIG. 17 is a schematic diagram of a display device provided by an embodiment of the present disclosure. As illustrated by FIG. 17, the display device 500 includes the display substrate 100 described above. In this way, the display device can have the advantages of high resolution, low power consumption.

For example, the display device may be a display device such as an organic light emitting diode display device, and any product or component with a display function, such as a television, a digital camera, a mobile phone, a watch, a tablet computer, a notebook computer and a navigator, this embodiment is not limited thereto.

The following statements should be noted:
(1) The accompanying drawings involve only the structure(s) in connection with the embodiment(s) of the present disclosure, and other structure(s) can be referred to common design(s).
(2) In case of no conflict, the embodiments of the present disclosure and the features in the embodiments can be combined with each other to obtain new embodiments.

What have been described above are only exemplary embodiments of the present disclosure and are not intended to limit the scope of protection of the present disclosure, and the scope of protection of the present disclosure is determined by the appended claims.

1. A display substrate, comprising:
a base substrate;
a plurality of cathode lines, located on the base substrate;
a planarization layer, located at a side of the plurality of cathode lines away from the base substrate;
a pixel definition layer, located at a side of the planarization layer away from the plurality of cathode lines; and
a plurality of light emitting elements,
wherein the display substrate further comprises a plurality of conductive isolation columns, the plurality of conductive isolation columns are arranged in one-to-one correspondence with the plurality of light emitting elements, each of the plurality of conductive isolation columns is electrically connected with one of the plurality of cathode lines, and
each of the light emitting elements comprises an anode, a light emitting layer and a cathode, and the cathode of each of the light emitting elements is electrically connected with a corresponding conductive isolation column of the plurality of conductive isolation columns.

2. The display substrate according to claim 1, further comprising:
a plurality of pixel driving circuits, located at a side of the planarization layer close to the base substrate,
wherein the plurality of pixel driving circuits are arranged in one-to-one correspondence with the plurality of light emitting elements, and the anode of each of the light emitting elements is electrically connected with an output end of a corresponding pixel driving circuit of the plurality of pixel driving circuits.

3. The display substrate according to claim 1, wherein each of the plurality of conductive isolation columns is at least partially located at a side of the pixel definition layer away from the base substrate, and each of the plurality of conductive isolation columns is electrically connected with one of the cathode lines through a via hole passing through both the pixel definition layer and the planarization layer.

4. The display substrate according to claim 3, wherein each of the plurality of conductive isolation columns is partially located in the via hole passing through both the pixel definition layer and the planarization layer.

5. The display substrate according to claim 1, wherein the cathode of each of the light emitting elements is overlapped with a lateral surface of a corresponding conductive isolation column of the plurality of conductive isolation columns.

6. The display substrate according to claim 5, wherein the cathode of each of the light emitting elements is arranged in contact with the lateral surface of the corresponding conductive isolation column, or
the cathode of each of the light emitting elements is connected with the lateral surface of the conductive isolation column through a conductive structure.

7. (canceled)

8. The display substrate according to claim 1, wherein the plurality of light emitting elements comprise a first light emitting element, a second light emitting element and a third light emitting element, the first light emitting element comprises a first anode, a first light emitting layer and a first cathode, the second light emitting element comprises a second anode, a second light emitting layer, and a second cathode, the third light emitting element comprises a third anode, a third light emitting layer and a third cathode,
the first anode and the first cathode are configured to drive the first light emitting layer to emit light of a first color, the second anode and the second cathode are configured to drive the second light emitting layer to emit light of a second color, and the third anode and the third cathode are configured to drive the third light emitting layer to emit light of a third color.

9. The display substrate according to claim 8, wherein the plurality of cathode lines comprise a first cathode line, a second cathode line and a third cathode line, the plurality of conductive isolation columns comprise a first conductive isolation column, a second conductive isolation column and a third conductive isolation column,
the first conductive isolation column is electrically connected with the first cathode line and the first cathode of the first light emitting element respectively, the second conductive isolation column is electrically connected with the second cathode line and the second cathode of the second light emitting element respectively, and the third conductive isolation column is electrically connected with the third cathode line and the third cathode of the third light emitting element respectively,
the first cathode line, the second cathode line, and the third cathode line are configured to be loaded with different cathode voltages.

10. (canceled)

11. The display substrate according to claim 9, wherein an orthographic projection of the first conductive isolation column on the base substrate is located at periphery of an orthographic projection of the first light emitting element on the base substrate, an orthographic projection of the second conductive isolation column on the base substrate is located at periphery of an orthographic projection of the second light emitting element on the base substrate, and an orthographic projection of the third conductive isolation column on the base substrate is located at periphery of an orthographic projection of the third light emitting element on the base substrate.

12. (canceled)

13. The display substrate according to claim 9, wherein the first light emitting element further comprises a first opening, located in the pixel definition layer, the first anode is located at a side of the pixel definition layer close to the base substrate, and is exposed by the first opening, and the first light emitting layer is at least partially located in the first opening, to contact with the first anode;
the second light emitting element further comprises a second opening, located in the pixel definition layer, the second anode is located at a side of the pixel definition layer close to the base substrate, and is exposed by the second opening, and the second light emitting layer is at least partially located in the second opening, to contact with the second anode; and
the third light emitting element further comprises a third opening located in the pixel definition layer, the third anode is located at a side of the pixel definition layer close to the base substrate, and is exposed by the third opening, and the third light emitting layer is at least partially located in the third opening, to contact with the third anode.

14. The display substrate according to claim 13, wherein an orthographic projection of the first conductive isolation column on the base substrate surrounds an orthographic projection of the first opening of the first light emitting element on the base substrate, an orthographic projection of the second conductive isolation column on the base substrate surrounds an orthographic projection of the second opening of the second light emitting element on the base substrate, and an orthographic projection of the third conductive isolation column on the base substrate surrounds an orthographic projection of the third opening of the third light emitting element on the base substrate.

15. The display substrate according to claim 13, wherein an orthographic projection of the first conductive isolation column on the base substrate half surrounds an orthographic projection of the first opening of the first light emitting element on the base substrate, an orthographic projection of the second conductive isolation column on the base substrate half surrounds an orthographic projection of the second opening of the second light emitting element on the base substrate, and an orthographic projection of the third conductive isolation column on the base substrate half surrounds an orthographic projection of the third opening of the third light emitting element on the base substrate,
only one conductive isolation column is arranged between the first light emitting element and the second light emitting element that are adjacent to each other, between the second light emitting element and the third light emitting element that are adjacent to each other, and between the first light emitting element and the third light emitting element that are adjacent to each other, respectively.

16. The display substrate according to claim 13, wherein an orthographic projection of the first conductive isolation column on the base substrate is located at a side of an orthographic projection of an edge of the first opening of the first light emitting element on the base substrate, an orthographic projection of the second conductive isolation column on the base substrate is located at a side of an orthographic projection of an edge of the second opening of the second light emitting element on the base substrate, and an orthographic projection of the third conductive isolation column on the base substrate is located at a side of an orthographic projection of an edge of the third opening of the third light emitting element on the base substrate.

17. The display substrate according to claim 8, further comprising:
a first temporary encapsulation layer, located at a side of the first light emitting element away from the base substrate;
a second temporary encapsulation layer, located at a side of the second light emitting element away from the base substrate; and
a third temporary encapsulation layer, located at a side of the third light emitting element away from the base substrate;
wherein the first temporary encapsulation layer, the second temporary encapsulation layer and the third temporary encapsulation layer are independent with each other, and are spaced apart from each other.

18. The display substrate according to claim 17, further comprising:
an encapsulation layer, located at a side of the first temporary encapsulation layer, the second temporary encapsulation layer and the third temporary encapsulation layer away from the base substrate.

19. The display substrate according to claim 1, wherein an orthographic projection of each of the plurality of conductive isolation columns on the base substrate surrounds an orthographic projection of a corresponding light emitting element on the base substrate respectively, or
an orthographic projection of each of the plurality of conductive isolation columns on the base substrate half surrounds an orthographic projection of a corresponding light emitting element on the base substrate, or
an orthographic projection of each of the plurality of conductive isolation columns on the base substrate is located at a side of an orthographic projection of an edge of a corresponding light emitting element on the base substrate.

20-21. (canceled)

22. The display substrate according to claim 1, wherein only one of the conductive isolation columns is arranged between two adjacent light emitting elements.

23. The display substrate according to claim 1, further comprising:
a plurality of cathode connection lines, wherein each of the cathode connection lines is electrically connected with at least two cathode lines of the plurality of cathode lines,
wherein each of the cathode connection lines is located in a first conductive layer and extends along a first direction, each of the cathode lines is located in a second conductive layer and extends along a second direction, and the first direction is intersected with the second direction.

24. The display substrate according to claim 23, wherein the plurality of cathode lines comprise a plurality of first cathode lines, a plurality of second cathode lines and a plurality of third cathode lines, the plurality of cathode connection lines comprise a first cathode connection line, a second cathode connection line and a third cathode connection line,
two of the first cathode lines adjacent to each other in the first direction are electrically connected with a same first cathode connection line, two of the second cathode lines adjacent to each other in the first direction are electrically connected with a same second cathode connection line, and two of the third cathode lines adjacent to each other in the first direction are electrically connected with a same third cathode connection line.

25. (canceled)

26. A display device, comprising the display substrate according to claim 1.
